(19) United States
(12) Patent Application Publication
(10) Pub. No.: US 2025/0047388 A1
(43) Pub. Date: Feb. 6, 2025

(54) OPTICAL TRANSMITTER

(71) Applicant: Nippon Telegraph and Telephone Corporation, Tokyo (JP)

(72) Inventors: Shigeru Kanazawa, Musashino-shi, Tokyo (JP); Takahiko Shindo, Musashino-shi, Tokyo (JP); Meishin Chin, Musashino-shi, Tokyo (JP); Shohei Kosuga, Musashino-shi, Tokyo (JP)

(21) Appl. No.: 18/716,474

(22) PCT Filed: Dec. 7, 2021
(86) PCT No.: PCT/JP2021/044965

§ 371 Date: Jun. 4, 2024

(51) Int. Cl. H04B 10/50; H01S 5/02345; H04B 10/80

(52) U.S. Cl. CPC H04B 10/504; H01S 5/02345; H04B 10/80

(57) ABSTRACT

Optical axes of a chip and a spatial optical system are aligned, and a high frequency band is improved. Provided is an optical transmitter in which a chip to which a high frequency signal is applied is mounted on a subcarrier on which a high frequency wire is formed, the optical transmitter including a carrier on which an optical component of a spatial optical system sharing an optical axis with the chip and the subcarrier are mounted, and a ground block that is inserted between the carrier and the subcarrier and electrically conducts the carrier and the subcarrier.

### TECHNICAL FIELD

The present invention relates to an optical transmitter in which a chip to which a high frequency signal is applied and an optical component of a spatial optical system are mounted.

### BACKGROUND ART

As a light source of an optical transmitter applied to a next-generation ultrafast optical network, a directly modulated laser (DML) and an electro-absorption modulator integrated with DFB laser (EML) are known. The DML modulates the optical output by directly modulating the current injected into the semiconductor laser (see, for example, Non Patent Literature 1). The EML modulates continuous (CW) light output from a semiconductor laser (LD) by an EA modulator. The EML has an advantage that a large extinction ratio can be obtained and the LD and the EA modulator can be individually optimized as compared with the DML, but since the LD and the EA modulator are integrated in one chip (hereinafter, referred to as an EML chip), the structure is complicated and the producing process is also complicated.

FIG. 1 illustrates a structure of a conventional EML subassembly. FIG. 1(a) is a top view of a portion of an EML subassembly, and FIG. 1(b) is a cross-sectional view along a high frequency wire. In an EML subassembly 10, an EML chip 12 is mounted on a subcarrier 11 on which high frequency wires are integrated. Although not illustrated, a PD for monitoring optical signal intensity, a drive circuit of an LD, an RF circuit for driving and controlling an EA modulator, and the like are mounted on the subcarrier 11. In the EML chip 12, a distributed feedback (DFB) laser and an EA modulator are integrated, and a drive electrode 12a and a modulation electrode 12b are formed on an upper surface of the chip. The high frequency wire is a coplanar line 13 in which grounds 13b and 13c are disposed on both side surfaces of a signal line 13a. The RF circuit that drives and controls the EA modulator supplies a high frequency signal to the modulation electrode 12b via the coplanar line 13 and a bonding wire 14.

FIG. 2 illustrates a structure of a conventional lens mounting assembly. FIG. 2(a) is a top view of a portion of the lens mounting assembly, and FIG. 2(b) is a cross-sectional view along a high frequency wire. In the lens mounting assembly, an EML subassembly 10 illustrated in FIG. 1 and a lens holder 23 to which a lens 22 is fixed are mounted on a carrier 21. An output from the EA modulator integrated in the EML chip 12 is output to the outside via the lens 22. Therefore, in order to align the optical axes of the EA modulator and the lens, it is necessary to align the height from the upper surface of the carrier 21 to the center of a waveguide 12c of the EA modulator with the height from the upper surface of the carrier 21 to the center of the lens 22. Conventionally, since it is difficult to adjust the height (thickness) of the EML chip 12, the height (thickness) of the subcarrier 11 is used for adjustment.

However, when the thickness of the subcarrier 11 is increased, the high frequency signal causes substrate resonance inside the subcarrier 11, and thus there is a problem that the band of the EML is deteriorated. On the other hand, it is also conceivable to use a material having a low dielectric constant as the substrate of the subcarrier 11 so as not to generate substrate resonance. However, it is desirable to use a material having the same thermal expansion coefficient for the EML chip 12 and the subcarrier 11 so as not to apply stress to the EML chip 12. When the InP substrate is used as the EML chip 12, it is necessary to use aluminum nitride as the material of the subcarrier 11, and there is a problem that a material having a low dielectric constant cannot be selected.

### CITATION LIST

### Non Patent Literature

Non Patent Literature 1: S. kanazawa et. al., “30-km Error-Free Transmission of Directly Modulated DFB Laser Array Transmitter Optical Sub-Assembly for 100-Gb Application,” J. of Lightw. Technol., vol. 34, no. 15, pp. 3646-3652, 2016.

### SUMMARY OF INVENTION

An object of the present invention is to provide an optical transmitter capable of freely setting a height from a carrier to a waveguide of a chip and improving a high frequency band in order to align an optical axis between the chip and an optical component of a spatial optical system.

In order to achieve such an object, according to an embodiment of the present invention, there is provided an optical transmitter in which a chip to which a high frequency signal is applied is mounted on a subcarrier on which a high frequency wire is formed, the optical transmitter including a carrier on which an optical component of a spatial optical system sharing an optical axis with the chip and the subcarrier are mounted, and a ground block that is inserted between the carrier and the subcarrier and allows electrical conduction between the carrier and the subcarrier.

### BRIEF DESCRIPTION OF DRAWINGS

FIG. 1 is a diagram illustrating a structure of a conventional EML subassembly.

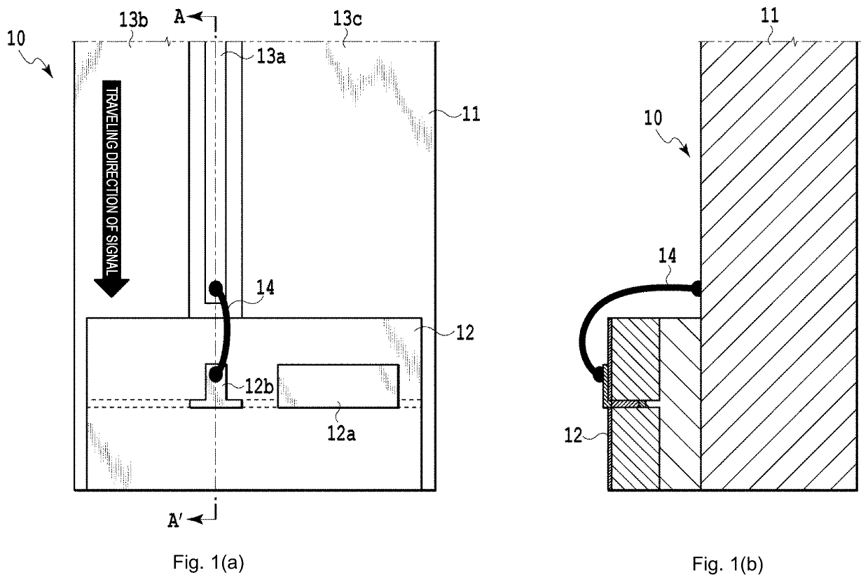

FIG. 2 is a diagram illustrating a structure of a conventional lens mounting assembly.

FIG. 3 is a diagram illustrating a structure of an EML subassembly according to a first embodiment.

FIG. 4 is a diagram illustrating a structure of a lens mounting assembly according to the first embodiment.

FIG. 5 is a diagram illustrating frequency response characteristics of the lens mounting assembly of the first embodiment.

FIG. 6 is a diagram illustrating a structure of a lens mounting assembly according to a second embodiment.

FIG. 7 is a diagram illustrating frequency response characteristics of the lens mounting assembly of the second embodiment.

### DESCRIPTION OF EMBODIMENTS

The following is a detailed description of an embodiment of the present invention with reference to the drawings.

### First Embodiment

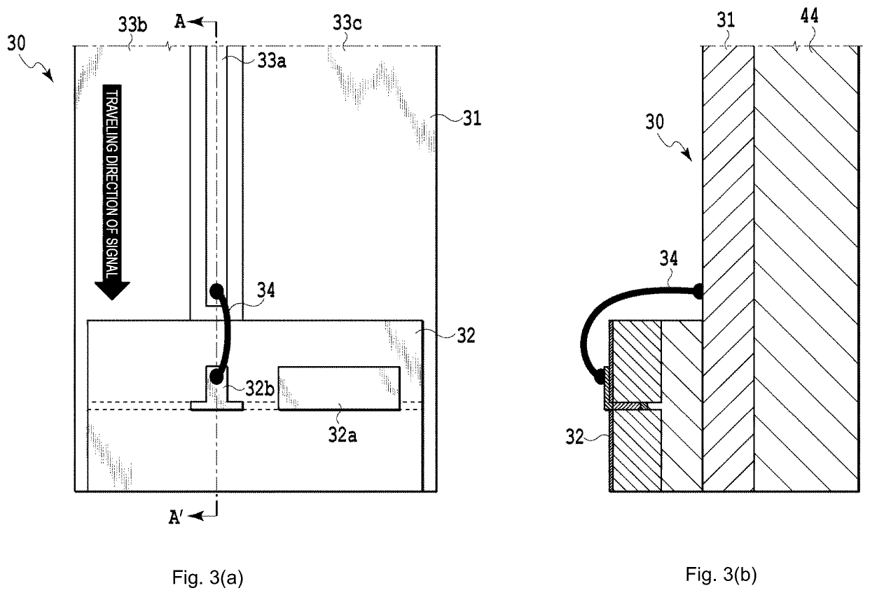

FIG. 3 illustrates a structure of the EML subassembly according to the first embodiment. FIG. 3(a) is a top view of a portion of the EML subassembly, and FIG. 3(b) is a cross-sectional view along a high frequency wire. In an EML subassembly 30, an EML chip 32 is mounted on a subcarrier 31 on which high frequency wires are integrated. In the EML chip 32, a DFB laser and an EA modulator are integrated, and a drive electrode 32a and a modulation electrode 32b are formed on an upper surface of the chip. The high frequency wire is a coplanar line 33 in which grounds 33b and 33c are disposed on both side surfaces of a signal line 33a. The RF circuit that drives and controls the EA modulator supplies a high frequency signal to the modulation electrode 32b via the coplanar line 33 and a bonding wire 34.

In the first embodiment, the grounded-coplanar line is shown, but a microstrip line having no ground on both side surfaces of a signal line may be used.

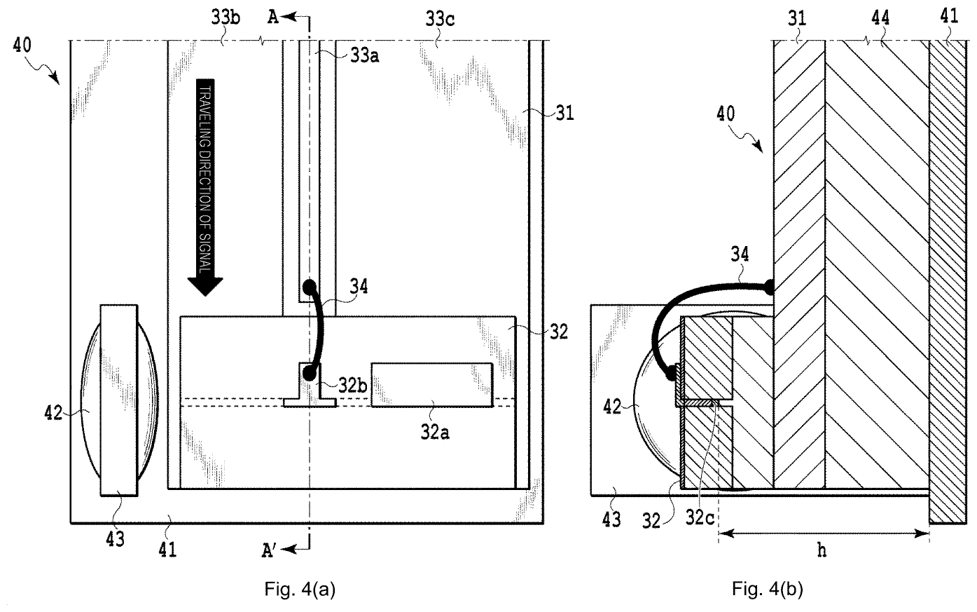

FIG. 4 illustrates a structure of a lens mounting assembly according to the first embodiment. FIG. 4(a) is a top view of a portion of the lens mounting assembly, and FIG. 4(b) is a cross-sectional view along a high frequency wire. In the lens mounting assembly, the EML subassembly 30 illustrated in FIG. 3 and a lens holder 43 to which the lens 42, which is an optical component of the spatial optical system, is fixed are mounted on the carrier 41. An output from the EA modulator integrated in the EML chip 32 is output to the outside via the lens 22. Therefore, in order to align the optical axes of the EA modulator and the lens, the height from the upper surface of the carrier 41 to the center (optical axis) of a waveguide 32c of the EA modulator and the height from the upper surface of the carrier 41 to the center (optical axis) of the lens 42 need to be the same.

In the first embodiment, the EML subassembly 30 is mounted on the carrier 41 via a ground block 44, and the height (thickness) of the ground block 44 is adjusted to align the height of the center of the waveguide 32c with the center of the lens 42. The thickness of the EML chip 32 is 150 μm, the thickness of the subcarrier 31 is 150 μm, and the height from the upper surface of the carrier 41 to the center of the lens 42 is 700 μm. The waveguide 32c of the EA modulator integrated in the EML chip 32 is an embedded waveguide, but may be considered to be on the upper surface of the EML chip 32 with a thickness 2 orders of magnitude thinner than the size of the chip. Therefore, the thickness of the ground block 44 was set to 400 μm.

As the subcarrier 31, aluminum nitride which is a material having the same thermal expansion coefficient as that of the EML chip 32 is used. The surface of the ground block 44 is gold-plated using Kovar. The ground block 44 allows electrical conduction between the subcarrier 31 and the carrier 41, and can provide a low-impedance ground connection and a sufficient heat dissipation path for the EML chip 32. The subcarrier 31 and the ground block 44 are bonded using solder with a small tolerance of height.

For example, in the case of an EML chip using an InP substrate, the thickness of the subcarrier is desirably 250 μm or less in order to suppress substrate resonance of a high frequency signal. Therefore, according to the first embodiment, it is not necessary to increase the thickness of the subcarrier 31, the substrate resonance of the high frequency signal can be suppressed, and the band deterioration of the EML can be suppressed. In addition, since the subcarrier 31 made of a material having a thermal expansion coefficient equal to that of the EML chip 32 can be used, the influence of stress on the EML chip 32 can be suppressed, and band deterioration can be suppressed.

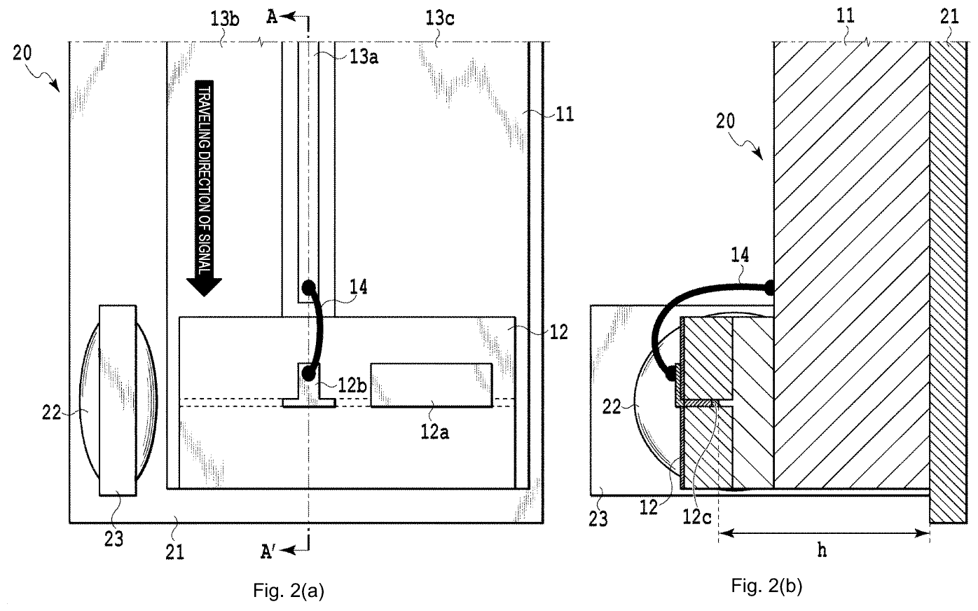

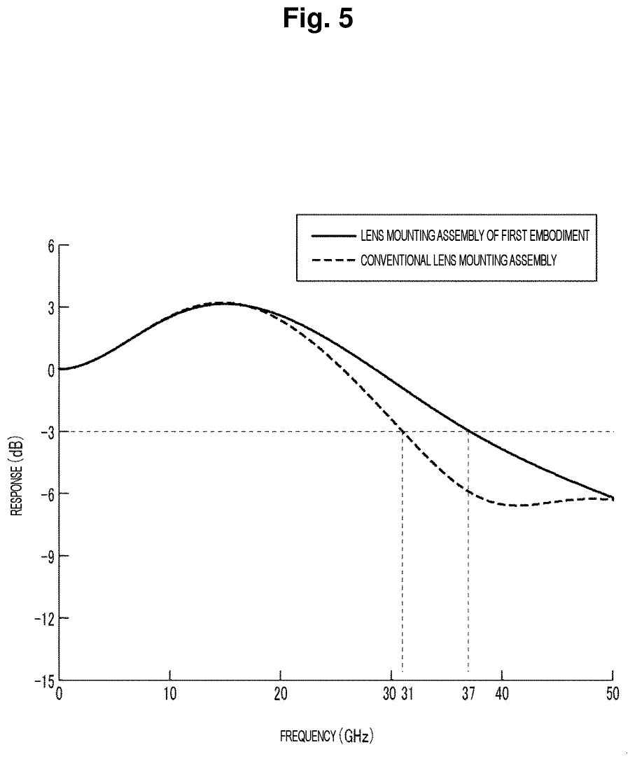

FIG. 5 illustrates frequency response characteristics of the lens mounting assembly of the first embodiment. The lens mounting assembly illustrated in FIG. 4 and the conventional lens mounting assembly illustrated in FIG. 2 were produced, and the frequency response characteristics were compared. The subcarrier 11 of the conventional lens mounting assembly is made of aluminum nitride and has a thickness of 550 μm.

In the conventional lens mounting assembly, the 3 dB band is about 31 GHz, but in the lens mounting assembly of the first embodiment, the 3 dB band can be improved to 37 GHz. For example, in a case of applying to an ultrahigh-speed optical network with a baud rate of 50 Gbaud of a modulated signal, a band of 35 GHz or more, which is about 0.7 times the baud rate, is required. Although the conventional lens mounting assembly cannot meet this requirement, the lens mounting assembly of the first embodiment can realize an optical transmitter that meets this requirement.

According to the first embodiment, the height from the carrier to the output waveguide of the EML chip can be freely set, and the high frequency band of the EML can be improved.

### Second Embodiment

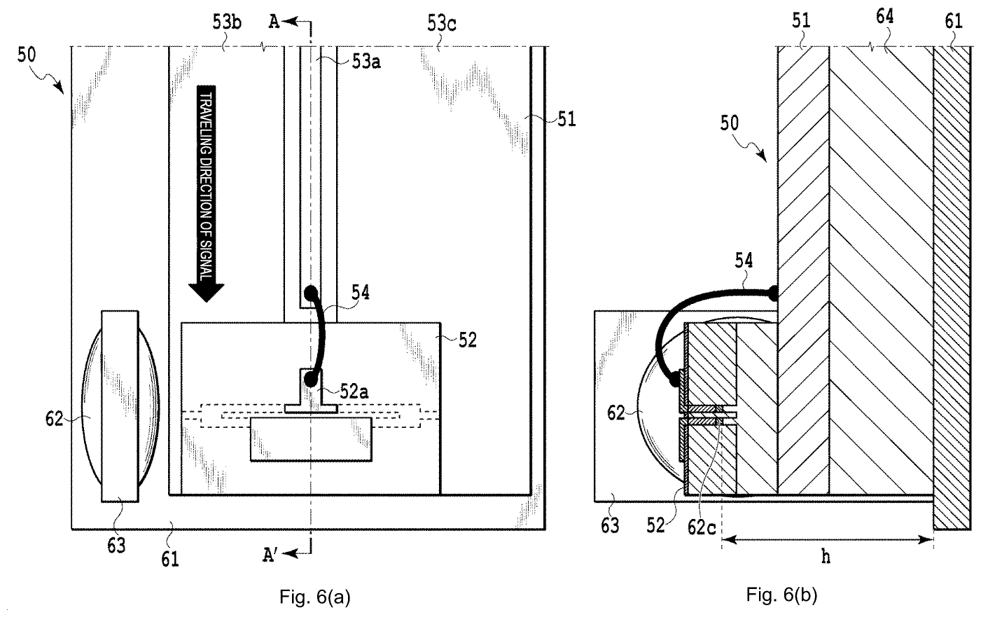

FIG. 6 illustrates a structure of a lens mounting assembly according to a second embodiment. In the first embodiment, the EML as the light source of the optical transmitter has been described as an example, but in the second embodiment, a subassembly of a single optical modulator will be described as an example. A Mach-Zehnder interferometer modulator (MZM) is used as the optical modulator.

FIG. 6(a) is a top view of a portion of the lens mounting assembly, and FIG. 6(b) is a cross-sectional view along a high frequency wire. In an MZM subassembly 50, an MZM chip 52 is mounted on a subcarrier 51 on which high frequency wires are integrated. Although not illustrated, a PD for monitoring optical signal intensity, an RF circuit for driving and controlling the MZM, and the like are mounted on the subcarrier 51. The MZM chip 52 has two arm waveguides as a Mach-Zehnder interferometer, and a modulation electrode 52a formed in one arm waveguide is formed on an upper surface of the chip. The high frequency wire is a coplanar line 53 in which grounds 53b and 53c are disposed on both side surfaces of a signal line 53a. The RF circuit that drives and controls the MZM supplies a high frequency signal to the modulation electrode 52b via the coplanar line 53 and a bonding wire 54.

In also the second embodiment, the grounded-coplanar line is shown, but a microstrip line having no ground on both side surfaces of the signal line may be used.

In the lens mounting assembly, the MZM subassembly 50 described above and a lens holder 63 to which the lens 62, which is an optical component of the spatial optical system, is fixed are mounted on a carrier 61. An output from the output waveguide of the MZM is output to the outside via the lens 62. Therefore, in order to align the optical axes of the MZM and the lens, the height from the upper surface of the carrier 61 to the center (optical axis) of a waveguide 52c of the MZM and the height from the upper surface of the carrier 61 to the center (optical axis) of the lens 62 need to be the same.

In the second embodiment, the MZM subassembly 50 is mounted on the carrier 61 via a ground block 64, and the height (thickness) of the ground block 64 is adjusted to align the height of the center of the waveguide 52c with the center of the lens 62. The thickness of the MZM chip 52 is 150 μm, the thickness of the subcarrier 51 is 250 μm, and the height from the upper surface of the carrier 61 to the center of the lens 62 is 800 μm. The waveguide 52c of the MZM chip 52 is an embedded waveguide, but may be regarded as being on the upper surface of the MZM chip 52 with a thickness as thin as 2 orders of magnitude compared to the scale of the chip. Therefore, the thickness of the ground block 64 was set to 400 μm.

As the subcarrier 51, aluminum nitride which is a material having the same thermal expansion coefficient as that of the MZM chip 52 is used. The ground block 64 has a structure in which gold is vapor-deposited on the upper surface, the lower surface, and the side surface using an alumina substrate, and the upper and lower surfaces are electrically connected. The ground block 64 electrically conducts the subcarrier 51 and the carrier 61, and can provide a low-impedance ground connection and a sufficient heat dissipation path for the MZM chip 52. The subcarrier 51 and the ground block 64 are bonded using solder with a small tolerance of height.

For example, in the case of the MZM chip using an InP substrate, the thickness of the subcarrier is desirably 250 μm or less in order to suppress substrate resonance of a high frequency signal. Therefore, according to the second embodiment, it is not necessary to increase the thickness of the subcarrier 51, the substrate resonance of the high frequency signal can be suppressed, and the band deterioration as the MZM can be suppressed. In addition, since the subcarrier 51 made of a material having a thermal expansion coefficient equal to that of the MZM chip 52 can be used, the influence of stress on the MZM chip 52 can be suppressed, and band deterioration can be suppressed.

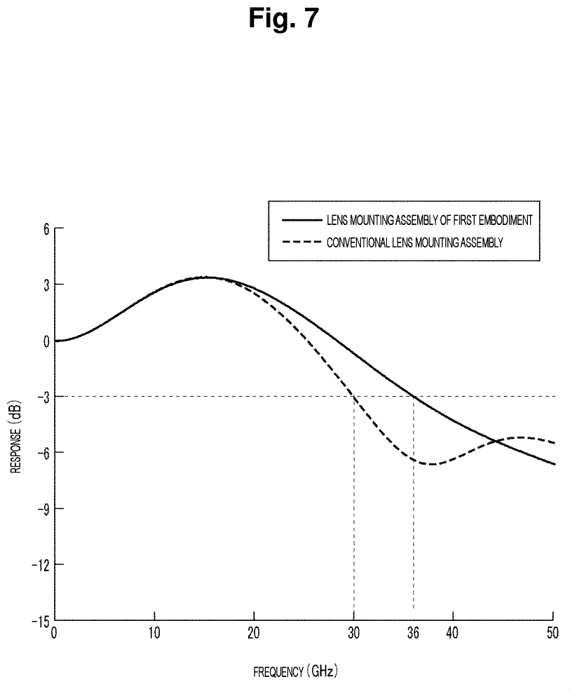

FIG. 7 illustrates frequency response characteristics of the lens mounting assembly of the second embodiment. The lens mounting assembly illustrated in FIG. 6 and a conventional MZM subassembly in which a ground block is not mounted, similarly to the first embodiment, were produced, and frequency response characteristics were compared. The subcarrier of the conventional lens mounting assembly is made of aluminum nitride and has a thickness of 650 μm.

In the conventional lens mounting assembly, the 3 dB band is about 30 GHz, but in the lens mounting assembly of the second embodiment, the 3 dB band can be improved to 36 GHz. For example, in a case of applying to an ultrahigh-speed optical network with a baud rate of 50 Gbaud of a modulated signal, a band of 35 GHz or more, which is about 0.7 times the baud rate, is required. Although the conventional lens mounting assembly cannot meet this requirement, the lens mounting assembly of the first embodiment can realize an optical transmitter that meets this requirement.

According to the second embodiment, the height from the carrier to the output waveguide of the MZM chip can be freely set, and the high frequency band of the MZM can be improved.

In the first and second embodiments, the EML chip and the MZM chip have been described as examples of the chip mounted on the carrier, but the present invention is not limited thereto. The present embodiment can be applied to an optical transmitter in which a chip sharing an optical axis with an optical component of a spatial optical system including a lens or the like, such as the above-described DML chip, is mounted. The ground block inserted between the carrier and the subcarrier can facilitate optical axis alignment between the chip and the optical component of the spatial optical system and improve a high frequency band of the chip. In addition, a low-impedance ground connection and a sufficient heat dissipation path can be provided for the chip.

1. An optical transmitter in which a chip to which a high frequency signal is applied is mounted on a subcarrier on which a high frequency wire is formed, the optical transmitter comprising:
a carrier on which an optical component of a spatial optical system sharing an optical axis with the chip and the subcarrier are mounted; and
a ground block that is inserted between the carrier and the subcarrier and allows electrical conduction between the carrier and the subcarrier.

2. The optical transmitter according to claim 1, wherein the ground block has a thickness that makes the height of the optical axis of the chip the same as the height of the optical axis of the optical component.

3. The optical transmitter according to claim 1, wherein the high frequency wire is a microstrip line or a grounded-coplanar line.

4. The optical transmitter according to claim 1, wherein the chip is an electro-absorption modulator integrated with a DFB laser, a Mach-Zehnder interferometer type optical modulator, or a directly modulated laser.

5. The optical transmitter according to claim 4, wherein baud rates of modulation signals of the electro-absorption modulator integrated with a DFB laser and the Mach-Zehnder interferometer type optical modulator are 50 Gbaud or more.

6. The optical transmitter according to claim 1, wherein
an InP substrate is used for the chip, and
the subcarrier is made of aluminum nitride and has a thickness of 250 μm or less.

7. The optical transmitter according to claim 2, wherein the chip is an electro-absorption modulator integrated with a DFB laser, a Mach-Zehnder interferometer type optical modulator, or a directly modulated laser.

8. The optical transmitter according to claim 3, wherein the chip is an electro-absorption modulator integrated with a DFB laser, a Mach-Zehnder interferometer type optical modulator, or a directly modulated laser.

9. The optical transmitter according to claim 2, wherein
an InP substrate is used for the chip, and
the subcarrier is made of aluminum nitride and has a thickness of 250 μm or less.

10. The optical transmitter according to claim 3, wherein
an InP substrate is used for the chip, and
the subcarrier is made of aluminum nitride and has a thickness of 250 μm or less.

11. The optical transmitter according to claim 4, wherein
an InP substrate is used for the chip, and
the subcarrier is made of aluminum nitride and has a thickness of 250 μm or less.

12. The optical transmitter according to claim 5, wherein
an InP substrate is used for the chip, and
the subcarrier is made of aluminum nitride and has a thickness of 250 μm or less.
